(19) United States
(12) Patent Application Publication
(10) Pub. No.: US 2015/0054391 A1
(43) Pub. Date: Feb. 26, 2015

(54) PLATE-SHAPED CASING MEMBER AND INJECTION MOLDING METHOD FOR THE SAME

(71) Applicant: Panasonic Corporation, Osaka (JP)

(72) Inventors: Yoshinari MATSUYAMA, Osaka (JP); Shintaro TANAKA, Osaka (JP); Haruka KANEKO, Osaka (JP); Tetsuya KAWAMOTO, Osaka (JP)

(73) Assignee: Panasonic Corporation, Osaka (JP)

(21) Appl. No.: 14/198,036

(22) Filed: Mar. 5, 2014

(30) Foreign Application Priority Data
Aug. 23, 2013 (JP) 2013-173667
Feb. 25, 2014 (JP) 2014-034331

(51) Int. Cl. H05K 5/04; B22D 17/22; G06F 1/16; B22D 17/00

(52) U.S. Cl. CPC H05K 5/04; B22D 17/005; B22D 17/2245; G06F 1/1613
USPC 312/223.1; 164/113

(57) ABSTRACT

A plate-shaped casing member includes a front surface and a rear surface. The rear surface of the plate-shaped casing member has a plurality of meandering ribs. The front surface may have a convex portion raised in a projecting manner. The rear surface may have a concave portion having a concave face which corresponds to the convex portion on the front surface. The plurality of meandering ribs may be formed on the concave portion of the rear surface.

### CROSS-REFERENCE TO RELATED APPLICATIONS

This application claims the priorities of Japanese Patent Application No. 2013-173667 filed in Japan on Aug. 23, 2013 and Japanese Patent Application No. 2014-34331 filed in Japan on Feb. 25, 2014, the contents of which are hereby incorporated by references.

### BACKGROUND

1. Technical Field

The present disclosure relates to a plate-shaped casing member and an injection molding method for the same.

2. Related Art

There has been known a casing where a raised portion which is raised in a projecting manner is formed on a front surface of the casing, and ribs are integrally formed on an inner surface side of the raised portion (see Japanese Patent Laid-open Publication No. 2007-272860, for example).

There has been also known a casing provided with a rear surface panel which covers a rear surface side of a display panel, wherein thin wall portions having a small wall thickness and thick wall portions formed on portions of the thin wall portions and having a large thickness in the direction toward the display panel are formed on a surface of the rear surface panel which faces the display panel in an opposed manner (see Japanese Patent Laid-open Publication No. 2010-113708, for example).

The casings disclosed in Japanese Patent Laid-open Publication Nos. 2007-272860 and 2010-113708 have high strength in the direction that the raised portions are raised or in the direction along the thick wall portions (short axis direction). However, recently, casings are required to exhibit higher strength also to bending of the casing in the direction perpendicular to the above-mentioned directions (in the long axis direction).

### SUMMARY

One non-limiting and exemplary embodiments provides a plate-shaped casing member which has high strength.

In one general aspect, the techniques disclosed here feature: a plate-shaped casing member including:

a front surface; and

a rear surface having a plurality of meandering ribs formed on the rear surface.

In the plate-shaped casing member according to the present disclosure, the plurality of meandering ribs are formed on the rear surface and hence, the plate-shaped casing member according to the present disclosure is effectively used as a plate-shaped casing member having high strength.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a plan view of a rear surface side of a plate-shaped casing member according to a first embodiment;

FIG. 2 is a perspective view of the rear surface side of the plate-shaped casing member shown in FIG. 1;

FIG. 3 is a plan view of a portion of the plate-shaped casing member shown in FIG. 1;

FIG. 4 is a cross-sectional view of the plate-shaped casing member as viewed from the direction of A-A in FIG. 3;

FIG. 5 is a cross-sectional view of the plate-shaped casing member along meandering ribs;

FIG. 6 is a perspective view showing an external appearance of a laptop personal computer which uses the plate-shaped casing member according to the first embodiment at a display portion thereof with a display panel opened;

FIG. 7 is a plan view showing the external appearance of the laptop personal computer shown in FIG. 6 with the display panel closed; and

FIG. 8 is a cross-sectional view of the plate-shaped casing member as viewed from the direction B-B in FIG. 7.

### DETAILED DESCRIPTION

A plate-shaped casing member according to a first aspect, including:

a front surface; and

a rear surface having a plurality of meandering ribs formed on the rear surface.

Further, as a plate-shaped casing member of a second aspect, in the first aspect, wherein the front surface has a convex portion raised in a projecting manner, the convex portion being formed on the front surface, and

the rear surface has a concave portion having a concave face, the concave portion being formed on the rear surface, the concave face being corresponding to the convex portion formed on the front surface, and

the plurality of meandering ribs is formed on the concave portion formed on the rear surface.

Further, as a plate-shaped casing member of a third aspect, in the second aspect, wherein the rib formed on the concave portion formed on the rear surface has a height lower than a height of an edge portion which constitutes a periphery of the concave portion.

Further, as a plate-shaped casing member of a fourth aspect, in the second aspect, wherein the convex portion is continuously formed in a short axis direction of the casing member.

Further, as a plate-shaped casing member of a fifth aspect, in the fourth aspect, wherein the concave portion is continuously formed in the short axis direction of the casing member.

Further, as a plate-shaped casing member of a sixth aspect, in the first aspect, wherein a top portion of the rib forms a flat surface along an extending direction of the rib.

Further, as a plate-shaped casing member of a seventh aspect, in the first aspect, wherein the rib is formed such that the central direction of the meander of the rib is arranged parallel to the short axis direction of the casing member.

Further, as a plate-shaped casing member of an eighth aspect, in the first aspect, wherein the plurality of ribs are formed such that the central directions of the meanders of the ribs are arranged parallel to each other.

Further, as a plate-shaped casing member of a ninth aspect, in the first aspect, wherein the plurality ribs are arranged such that meandering cycles of the ribs are synchronized with each other.

Further, as a plate-shaped casing member of a tenth aspect, in the first aspect, wherein the plurality of ribs is arranged equidistantly from each other.

An injection molding method for a plate-shaped casing member according to an eleventh aspect, the method comprising:

preparing two dies for injection molding which includes a first die having a plurality of meandering concave grooves and a second die which is joinable to and separable from the first die;

clamping the first die and the second die together;

injecting a molten material into a hollow portion formed between the first die and the second die along the central direction of a meander of the plurality of meandering concave grooves formed on the first die, and solidifying by cooling the molten material so as to form a molded material; and

opening the first die and the second die and taking out a plate-shaped casing member made of the molded material formed by injection molding.

Further, as a method of a twelfth aspect, in the eleventh aspect, wherein the first die has a convex portion raised in a projecting manner, and the plurality of meandering concave grooves are formed on a top portion of the convex portion, and

the second die has a concave portion having a concave face which faces the convex portion of the first die in an opposed manner when the first die and the second die are clamped together.

Further, as a method of a thirteenth aspect, in the eleventh aspect, wherein a bottom of the groove formed on the first die is arranged as forming a flat surface along the extending direction of the groove.

Further, as a method of a fourteenth aspect, in the eleventh aspect, wherein the plurality of grooves are arranged such that the central directions of the meanders of the grooves are arranged parallel to each other.

Further, as a method of a fifteenth aspect, in the eleventh aspect, wherein the plurality of grooves are arranged such that meandering cycles of the grooves are synchronized with each other.

Further, as a method of a sixteenth aspect, in the eleventh aspect, wherein the plurality of grooves are arranged such that the central directions of the meanders of the grooves are arranged equidistantly.

Hereinafter, an embodiment will be described in detail by reference to drawings appropriately. However, the excessively detailed explanation may be omitted when appropriate. For example, the detailed explanation of well-known matters or the repeated explanation of the substantially same constitution may be omitted. These are taken for preventing the explanation made hereinafter from being unnecessarily redundant thus facilitating the understanding of the present disclosure by those who are skilled in the art.

Inventors of this disclosure provides the accompanying drawings and the explanation made hereinafter for enabling those who are skilled in the art to sufficiently understand the present disclosure, and the subjects defined in the claims are not intended to be restricted by the accompanying drawings and the explanation made hereinafter. In the drawings, same symbols are used to indicate substantially identical parts.

### First Embodiment

### Plate-Shaped Casing Member

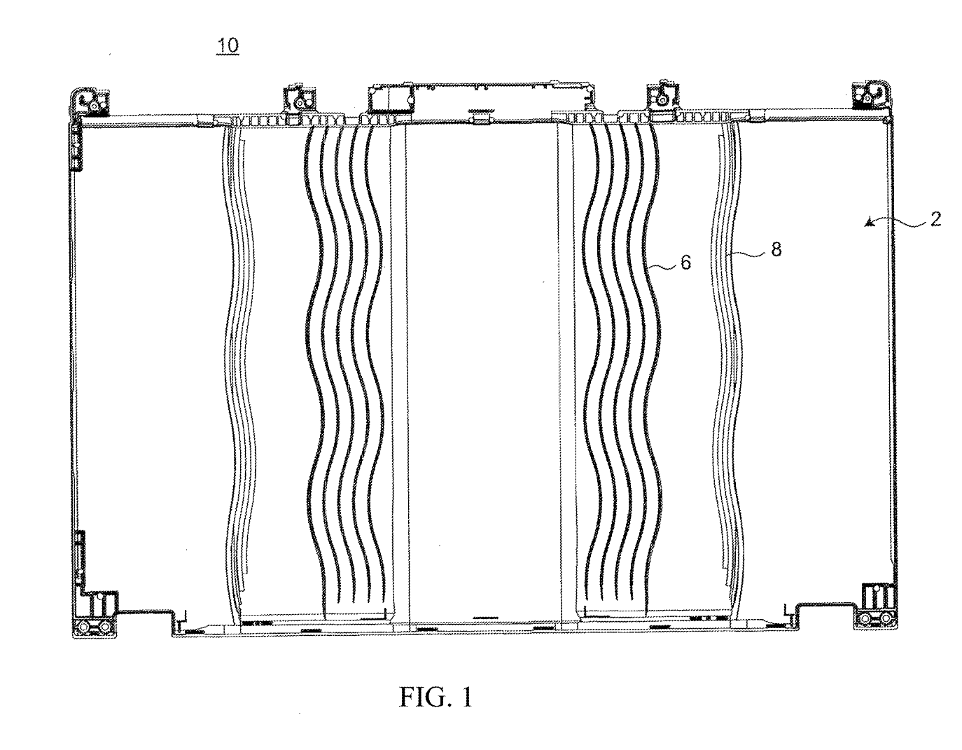

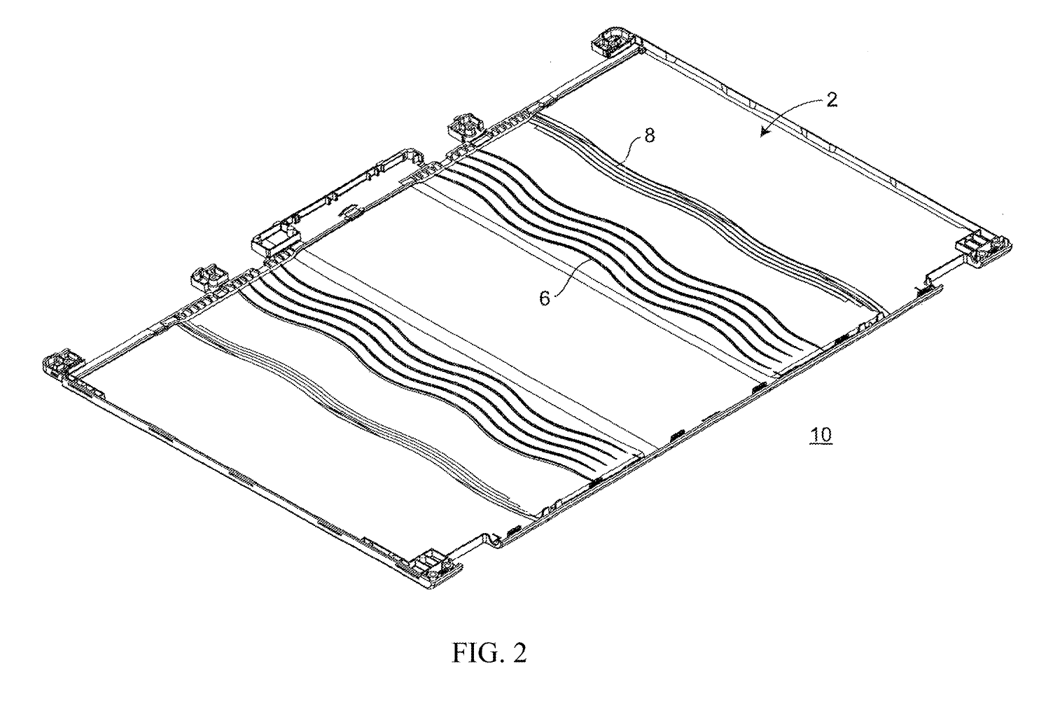

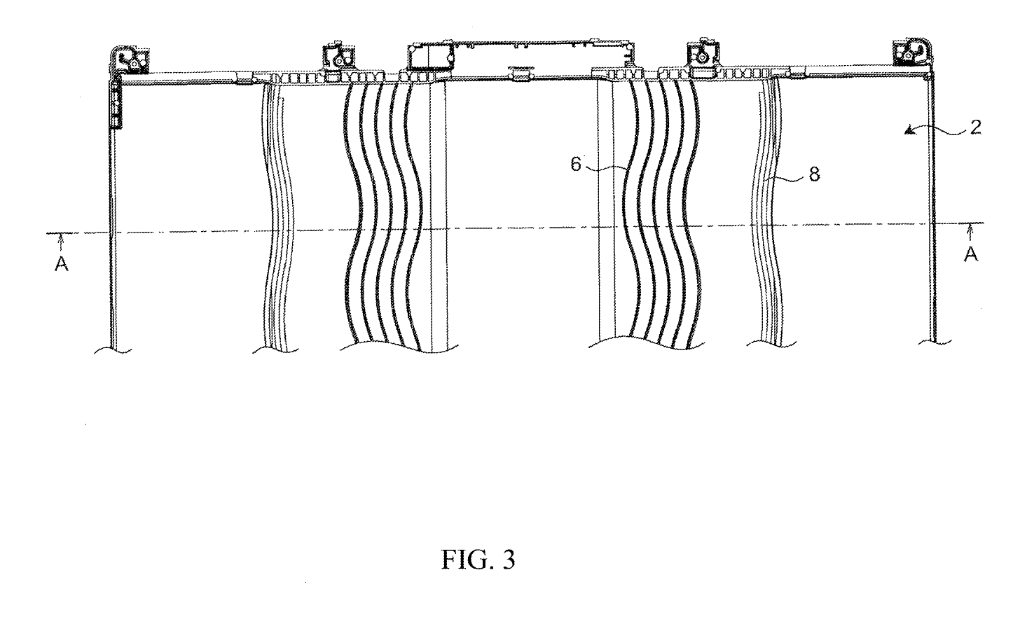

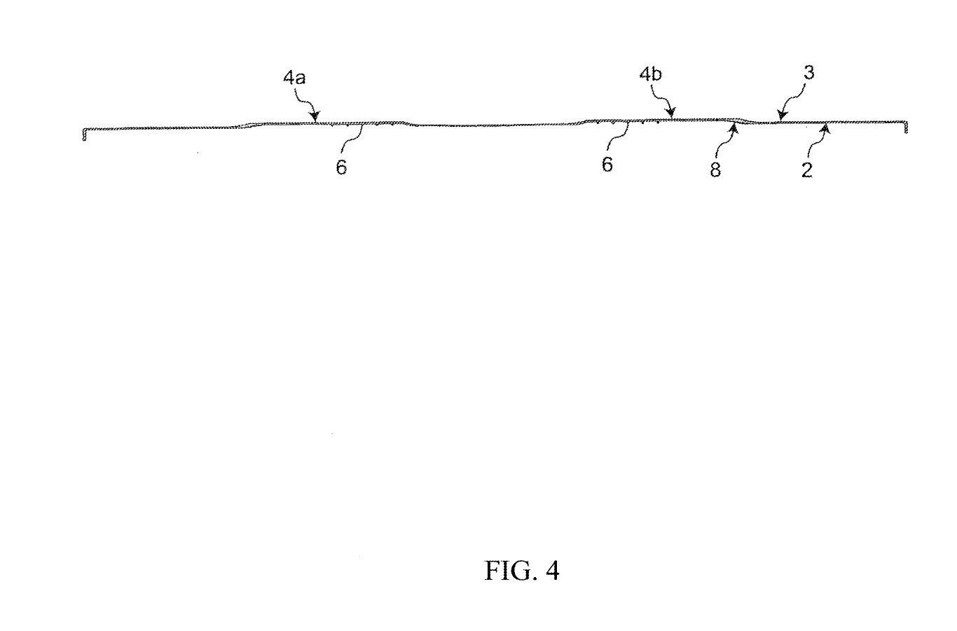

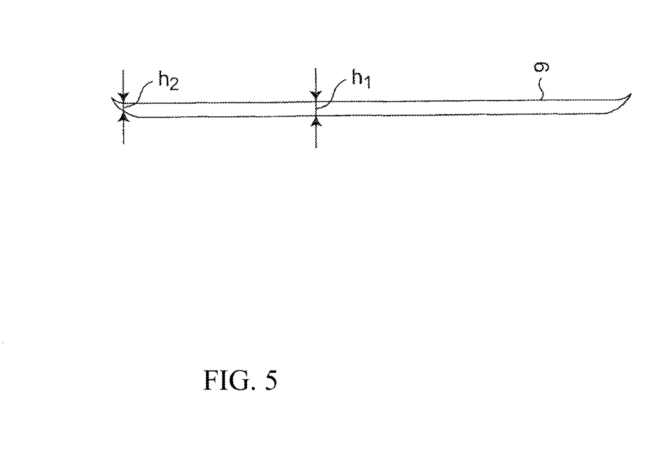

FIG. 1 is a plan view of a rear surface side of a plate-shaped casing member 10 according to a first embodiment. FIG. 2 is a perspective view of the rear surface side of the plate-shaped casing member 10 shown in FIG. 1. FIG. 3 is a plan view of a portion of a rear surface side of the plate-shaped casing member 10 shown in FIG. 1. FIG. 4 is a cross-sectional view of the plate-shaped casing member 10 as viewed from the direction of A-A in FIG. 3. FIG. 5 is a cross-sectional view of the plate-shaped casing member 10 along meandering ribs 6.

The plate-shaped casing member 10 includes a front surface 3 and a rear surface 2 having a plurality of meandering ribs 6 formed on the rear surface 2. Further, the front surface 3 has convex portions 4a, 4b which are raised in a projecting manner. The rear surface 2 has concave portions each having a concave face corresponding to the convex portions 4a, 4b formed on the front surface 3. The plurality of meandering ribs 6 are formed on the concave portion of the rear surface 2. Forming the plurality of meandering ribs 6 allows to suppress the deformation such as bending of the casing member 10 which may be caused by an external force. Specifically, the vertically extending ribs 6 are formed on the rear surface 2 and hence, the casing member 10 may have high strength to a stress generated in the direction perpendicular to the rear surface 2. Further, the casing member 10 has high strength not only to the bending generated using the extending direction of the meandering rib 6 (the central direction of the meandering rib 6) as a fulcrum but also to the bending generated using the direction perpendicular to the extending direction of the rib 6 as a fulcrum. It is considered that this is because the rib 6 meanders so that the rib 6 includes portions which intersect the bending direction whereby the plate-shaped casing member 10 has high strength also to a bending stress having a component perpendicular to the extending direction of the rib 6. Accordingly, the rib 6 has high strength not only to a stress generated in the extending direction of the rib 6 but also to stresses applied to the plate-shaped casing member 10 from all directions such as the in-plane direction and the vertical direction. Particularly, the ribs 6 can suppress the deformation of the plate-shaped casing member 10 caused by a stress generated in the in-plane direction. In this manner, according to the plate-shaped casing member 10, the plurality of meandering ribs 6 formed on the concave portions of the rear surface 2 allow to enhance the resistance of the plate-shaped casing member 10 to stresses and hence, the plate-shaped casing member 10 can acquire high strength. The extending direction of the rib 6 means the direction of an imaginary straight line assuming that there exists such an imaginary straight line with which the rib 6 intersects from the different directions alternately.

Hereinafter, constitutional elements of the plate-shaped casing member 10 are explained.

### <Plate-Shaped Casing Member>

The plate-shaped casing member 10 includes the front surface 3 and the rear surface 2. The plate-shaped casing member 10 can be used as a casing member which stores electronic equipment, for example, a laptop personal computer therein. The laptop personal computer is only an example of the electronic equipment and hence, the electric equipment is not limited to the laptop personal computer.

The plate-shaped casing member 10 may have a rectangular shape. When the casing member 10 stores a display panel, for example, an aspect ratio of the casing member 10 may be set to 4:3, 16:10, 16:9 or the like. The aspect ratio of the casing member 10 is not limited to the above-mentioned values.

As a material for forming the plate-shaped casing member 10, for example, a metal alloy having a low melting point such as a magnesium alloy can be used. A material for forming the plate-shaped casing member 10 is not limited to a magnesium alloy. For example, other metal alloys, resin materials and the like may be used.

### <Front Surface>

The front surface 3 of the plate-shaped casing member 10 may have the various structures thereon for enhancing strength of plate-shaped casing member 10, or may have various ornaments thereon for enabling the plate-shaped casing member 10 to acquire an aesthetic appearance or the like. For example, convex portions 4a, 4b which are raised in a projecting manner may be formed on the front surface 3a. The structure having such convex portions 4a, 4b is referred to as a bonnet structure. By forming the convex portions 4a, 4b which are raised in a projecting manner on the front surface 3, it is possible to form the plate-shaped casing member 10 having high strength.

As shown in FIG. 4, in this plate-shaped casing member 10, the convex portions 4a, 4b are formed on two portions at left and right sides of the front surface 3 with respect to the center of the front surface 3. However, it is not always necessary to form the convex portion on the plurality of portions of the front surface 3. The convex portions 4a, 4b may be arranged parallel to the short axis direction of the plate-shaped casing member 10. Alternatively, the convex portions 4a, 4b may be arranged parallel to the long axis direction. When a convex portion is formed on only one portion, for example, a convex portion may be formed at the center of the front surface 3 parallel to the short axis direction.

### <Rear Surface>

The plurality of meandering ribs 6 are formed on the rear surface 2 of the plate-shaped casing member 10. On the rear surface 2, concave portions having concave faces corresponding to the convex portions 4a, 4b formed on the front surface 3 may be formed. In this case, a plurality of meandering ribs 6 may be formed on each concave portion of the rear surface 2. The concave portions are formed at left and right sides of the rear surface 2 with respect to the center of the rear surface 2 in the long axis direction. The concave portions may be formed parallel to the short axis direction of the plate-shaped casing member 10.

In the plate-shaped casing member 10 of this embodiment, the plurality of meandering ribs 6 are formed on two concave portions on left and right sides of the rear surface 2 with respect to the center of the rear surface 2 respectively. However, it is sufficient that the plurality of meandering ribs 6 is formed on at least one portion.

### <Rib>

The plurality of meandering ribs 6 are formed on the rear surface 2. The plurality of meandering ribs 6 may be formed on the concave portions. The ribs 6 may be formed with a height lower than a height of an edge portion which constitutes a periphery of the concave portion. The above configuration of ribs 6 allows to prevent the ribs 6 from being brought into contact with a rear surface side of a display panel when the display panel is stored in the plate-shaped casing member 10. The ribs 6 may be formed such that the top portion keeps the same plane along the extending direction. Here, “same plane” means that when the plate-shaped casing member 10 is placed on a flat surface with the front surface 3 down, the height of the rib 6 from the flat surface becomes constant along the extending direction of the rib 6 (FIG. 5). As shown in FIG. 5, an outer surface of the casing member is gradually curved as the outer surface of the casing member approaches an edge portion of the casing member. As a result, an apparent height of the rib 6 from a bottom surface of the concave portion is gradually decreased. For example, compared a height h1 of the rib 6 from the bottom surface at the center portion to a height h2 of the rib 6 from the bottom surface at the edge portions, the relationship of h2<h1 is found. As described above, the apparent height h2 of the rib 6 at the edge portion is decreased compared to the apparent height h1 of the rib 6 at the center portion and hence, cables or the like can be made to pass through the edge portion.

The ribs 6 may be formed along the direction of the concave portion. Specifically, the ribs 6 may be formed such that the extending direction of the meander of the ribs 6 is arranged parallel to the short axis direction of the plate-shaped casing member 10. In this case, the plate-shaped casing member 10 can acquire high strength particularly to a stress generated in the short axis direction.

The plurality of meandering ribs 6 may be arranged such that the central directions of the meanders of the respective meandering ribs 6 are arranged parallel to each other. The above configuration of ribs 6 allows to further enhance strength of the plate-shaped casing member 10. The plurality of meandering ribs 6 may be arranged such that meandering cycles of the respective ribs are synchronized with each other. “Meandering cycles are synchronized with each other” means that the extending directions of the adjacent ribs are substantially equal to each other, and a distance between the adjacent ribs defined in the direction perpendicular to the extending direction is approximately constant. The above configuration of ribs 6 allows to further enhance strength of the plate-shaped casing member 10. The plurality of ribs 6 may be arranged equidistantly. According to the above configuration of ribs 6, the plate-shaped casing member 10 can acquire stable strength and, at the same time, the flow of a molten material can be made more uniform at the time of forming the plate-shaped casing member 10 by injection molding thus suppressing the generation of sink marks on a proximal portion of the rib 6.

The rib 6 may be formed in a tapered manner such that a width of the rib 6 is gradually narrowed from a proximal portion on a rear surface side to a top portion. According to the above configuration of ribs 6, the plate-shaped casing member 10 can acquire an advantageous effect that the ribs 6 can be smoothly removed from a mold at the time of forming the plate-shaped casing member 10 by injection molding.

### <Meandering Level-Difference Portion>

In this plate-shaped casing member 10, a plurality of meandering level-difference portions 8 may be formed on level-difference portions around the concave portions on the rear surface corresponding to the convex portions 4a, 4b on the front surface. In the meandering level-difference portion 8, a plurality of meandering surfaces is formed by way of level differences. According to forming the meandering level-difference portions 8, at the time of injection molding, the flow of a large amount of molten material in a thick wall portion can be dispersed to thin wall portions around the thick wall portion and hence, the flow of molten material can be made uniform as a whole. As a result, temperature difference hardly occurs and hence, the generation of sink marks can be suppressed. The plurality of meandering surfaces are formed by way of level differences and hence, a stress applied to the meandering level-difference portion 8 in the in-plane direction (the direction parallel to the meandering surfaces) can be dispersed leftward and rightward by the meandering level-difference portions 8 having a waveform shape, whereby the deformation of the plate-shaped casing member 10 which may be caused by a stress in the in-plane direction can be suppressed. the meandering level-difference portions 8 allows to enhance stress resistance to a stress applied to the plate-shaped casing member 10 from the direction perpendicular to the surface of the plate-shaped casing member 10. Accordingly, the plate-shaped casing member 10 having high strength can be acquired.

### <Laptop Personal Computer>

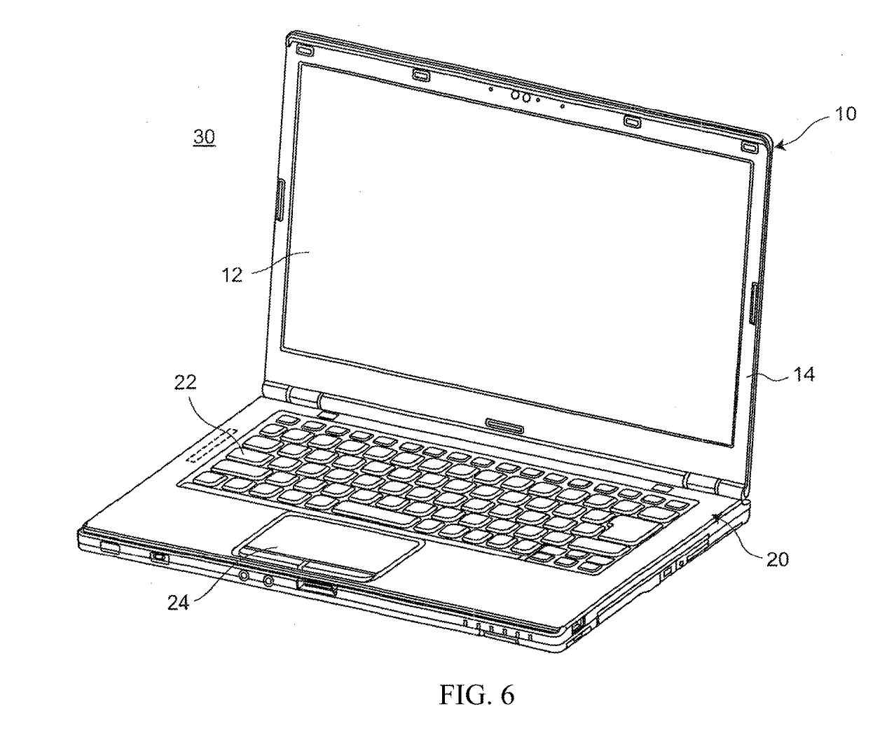

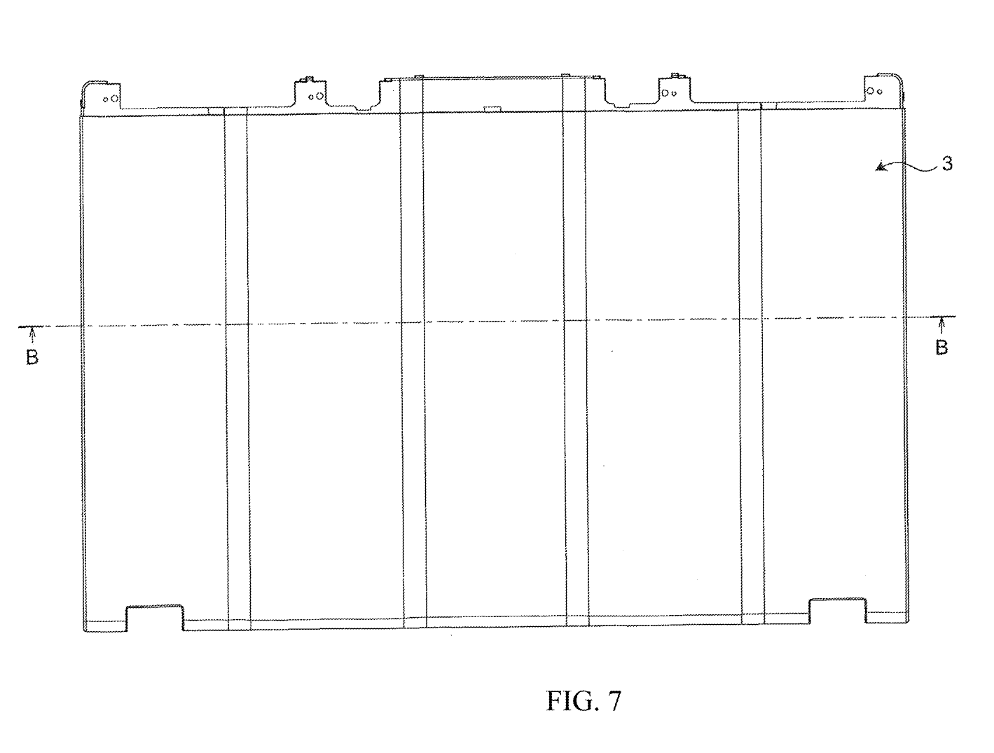

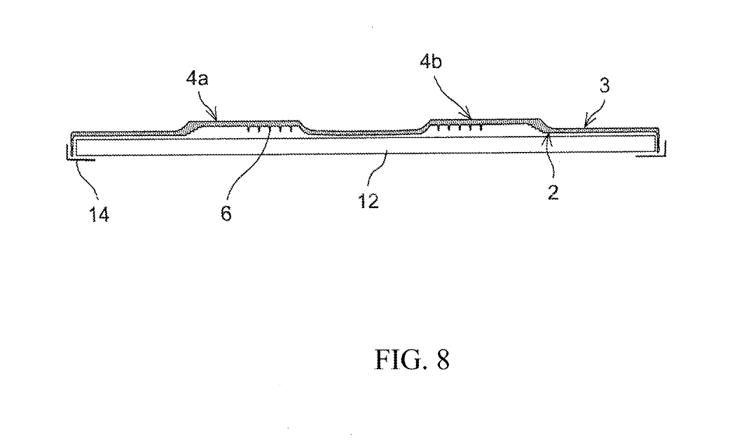

FIG. 6 is a perspective view showing an external appearance of a laptop personal computer 30 which uses the plate-shaped casing member 10 according to the first embodiment at a display portion thereof with a display panel 12 opened. FIG. 7 is a plan view showing the external appearance of the laptop personal computer 30 shown in FIG. 6 with the display panel 12 closed. FIG. 8 is a cross-sectional view of the plate-shaped casing member 10 taken along the direction B-B in FIG. 7.

The laptop personal computer 30 includes: the plate-shaped casing member (upper casing) 10 and a rear casing 14 which are used in a display part for holding the display panel 12; and a lower casing 20. In the plate-shaped casing member 10 which constitutes the upper casing, the plurality of meandering ribs 6 are formed on the concave portions on a rear surface side. The concave portions on a rear surface side correspond to the convex portions 4a, 4b formed on a front surface side. Accordingly, the plate-shaped casing member 10 can acquire high strength and hence, strength of the laptop personal computer 30 can be also enhanced.

### <Injection Molding Method for Plate-Shaped Casing Member>

The injection molding method for the plate-shaped casing member according to the first embodiment is explained hereinafter.

(1) Two injection molding dies which includes a first die and a second die joinable to and separable from the first die is prepared.

A plurality of meandering concave grooves are formed on the first die. Convex portions which are raised in a projecting manner may be formed on the first die. In this case, the plurality of meandering concave grooves may be formed on a top portion of the convex portion.

The second die may include a concave portion having a concave face which faces the convex portion of the first die in an opposed manner when the first die and the second die are clamped together.

(2) The first die and the second die are clamped together.

(3) A molten material is injected into a hollow portion formed between the first die and the second die along the central direction of the meander of the meandering grooves formed on the first die. Then, the molten material is solidified by cooling thus forming a molded material. Since the molten material is made to flow into the hollow portion along the central direction of the meander of the grooves as described above, the molten material is dispersed leftward and rightward by the meandering grooves and hence, the flow of molten material can be made uniform. That is, a large amount of molten material which flows fast at the convex portion is dispersed leftward and rightward by the meandering grooves and hence, the flow of the molten material can be made uniform as a whole. In this case, although a depth of the groove is set to only approximately several millimeters, for example, the grooves are formed in a meandering manner so that the grooves function as barrier walls which apply braking to the flow of the molten material.

(4) The first die and the second die are opened, and an injection-molded article (the plate-shaped casing member) made of the molded material formed by injection molding is taken out from the dies.

The plate-shaped casing member 10 can be manufactured through the above-mentioned steps.

According to the injection molding method for the plate-shaped casing member, the plurality of meandering grooves are formed on the first die, and a molten material is injected along the central direction of the meander of the grooves. Accordingly, the flow of the molten material can be made uniform and hence, the temperature difference hardly occurs whereby it is possible to suppress the generation of sink marks on the meandering ribs which are formed corresponding to the meandering grooves.

After the injection molding is completed, the plurality of meandering ribs can be formed corresponding to the meandering grooves formed on the first die. Accordingly, the deformation which may be caused by a stress can be suppressed. Firstly, the ribs formed perpendicular to the rear surface are formed on the rear surface and hence, the plate-shaped casing member has high strength to a stress generated in the direction perpendicular to the rear surface. Further, the plate-shaped casing member has high strength not only to a stress generated in the extending direction (central direction of the meander) of the meandering ribs but also to a stress generated in the direction perpendicular to the extending direction of the ribs. Accordingly, the plate-shaped casing member has high strength not only to a stress applied to the plate-shaped casing member in the extending direction of the ribs but also to stress applied to the plate-shaped casing member in all directions such as the in-plane direction and the vertical direction. Particularly, it is possible to suppress the deformation of the casing member which may be caused by a stress applied to the plate-shaped casing member in the in-plane direction. According to this embodiment, the plurality of meandering ribs formed on the concave portions on the rear surface allow to enhance the resistance of the plate-shaped casing member to stresses and hence, the plate-shaped casing member can acquire high strength.

Hereinafter, the respective constitutional members used in the injection molding method for the plate-shaped casing member are explained.

### <First Die>

The plurality of meandering concave grooves are formed on the first die. The convex portion which is raised in a projecting manner may be formed on the first die. In this case, the plurality of meandering concave grooves may be formed on a top portion of the convex portion. After the injection molding is completed, a surface of the molded product which is brought into contact with the first die constitutes a rear surface of the plate-shaped casing member, and the meandering grooves of the first die correspond to the meandering ribs of the plate-shaped casing member. After the injection molding is completed, the convex portion of the first die corresponds to the concave portion of the plate-shaped casing member.

### <Second Die>

A concave portion may be formed on the second die such that the concave portion faces the convex portion formed on the first die in an opposed manner when the first die and the second die are clamped together. After the injection molding is completed, a surface of the molded product which is brought into contact with the second die constitutes the front surface of the plate-shaped casing member. Also, the concave portion of the second die corresponds to the convex portion which is raised in a projecting manner on the front surface of the plate-shaped casing member.

### <Molten Material>

As the molten material, a molten material of a metal alloy having a low melting point such as a magnesium alloy can be used, for example. The molten material is not limited to the molten material of a magnesium alloy. For example, other metal alloys, resin materials and the like may be used.

The embodiment has been explained heretofore as an example of the technique according to the present disclosure. For this purpose, the attached drawings and the detailed explanation are provided.

Accordingly, the constitutional elements described in the accompanying drawings and the detailed description may also include not only the constitutional elements necessary for overcoming the problems but also constitutional elements which are unnecessary for overcoming the problems in order to exemplify the aforementioned techniques. Therefore, such unnecessary constitutional elements should not be immediately determined to be necessary, for the reason that these unnecessary constitutional elements are described in the accompanying drawings and the detailed description.

Further, the aforementioned embodiment is merely for exemplifying the techniques according to the present disclosure and, therefore, various changes, replacements, additions, omissions and the like can be made thereto within the scope of the claims and scopes equivalent thereto.

The present disclosure is applicable to a plate-shaped casing member having high strength. More specifically, the present disclosure is applicable to a plate-shaped casing member for electronic equipment such as a laptop personal computer.

1. A plate-shaped casing member comprising:
a front surface; and
a rear surface having a plurality of meandering ribs formed on the rear surface.

2. The plate-shaped casing member according to claim 1, wherein the front surface has a convex portion raised in a projecting manner, the convex portion being formed on the front surface, and
the rear surface has a concave portion having a concave face, the concave portion being formed on the rear surface, the concave face being corresponding to the convex portion formed on the front surface, and
the plurality of meandering ribs is formed on the concave portion formed on the rear surface.

3. The plate-shaped casing member according to claim 2, wherein the rib formed on the concave portion formed on the rear surface has a height lower than a height of an edge portion which constitutes a periphery of the concave portion.

4. The plate-shaped casing member according to claim 2, wherein the convex portion is continuously formed in a short axis direction of the casing member.

5. The plate-shaped casing member according to claim 4, wherein the concave portion is continuously formed in the short axis direction of the casing member.

6. The plate-shaped casing member according to claim 1, wherein a top portion of the rib forms a flat surface along an extending direction of the rib.

7. The plate-shaped casing member according to claim 1, wherein the rib is formed such that the central direction of the meander of the rib is arranged parallel to the short axis direction of the casing member.

8. The plate-shaped casing member according to claim 1, wherein the plurality of ribs are formed such that the central directions of the meanders of the ribs are arranged parallel to each other.

9. The plate-shaped casing member according to claim 1, wherein the plurality ribs are arranged such that meandering cycles of the ribs are synchronized with each other.

10. The plate-shaped casing member according to claim 1, wherein the plurality of ribs is arranged equidistantly from each other.

11. An injection molding method for a plate-shaped casing member, the method comprising the steps of:
preparing two dies for injection molding which includes a first die having a plurality of meandering concave grooves and a second die which is joinable to and separable from the first die;
clamping the first die and the second die together;
injecting a molten material into a hollow portion formed between the first die and the second die along the central direction of a meander of the plurality of meandering concave grooves formed on the first die, and solidifying by cooling the molten material so as to form a molded material; and
opening the first die and the second die and taking out a plate-shaped casing member made of the molded material formed by injection molding.

12. The injection molding method for a plate-shaped casing member according to claim 11, wherein the first die has a convex portion raised in a projecting manner, and the plurality of meandering concave grooves are formed on a top portion of the convex portion, and
the second die has a concave portion having a concave face which faces the convex portion of the first die in an opposed manner when the first die and the second die are clamped together.

13. The injection molding method for a plate-shaped casing member according to claim 11, wherein a bottom of the groove formed on the first die is arranged as forming a flat surface along the extending direction of the groove.

14. The injection molding method for a plate-shaped casing member according to claim 11, wherein the plurality of grooves are arranged such that the central directions of the meanders of the grooves are arranged parallel to each other.

15. The injection molding method for a plate-shaped casing member according to claim 11, wherein the plurality of grooves are arranged such that meandering cycles of the grooves are synchronized with each other.

16. The injection molding method for a plate-shaped casing member according to claim 11, wherein the plurality of grooves are arranged such that the central directions of the meanders of the grooves are arranged equidistantly.
